(19) United States
(12) Patent Application Publication
(10) Pub. No.: US 2020/0341053 A1
(43) Pub. Date: Oct. 29, 2020

(54) VERTICAL ULTRA LOW LEAKAGE PROBE CARD FOR DC PARAMETER TEST

(71) Applicant: TEPS CO., LTD., Hwaseong-si, Gyeonggi-do (KR)

(72) Inventors: Jaebok LEE, Hwaseong-si, Gyeonggi-do (KR); Daewon KIM, Hwaseong-si, Gyeonggi-do (KR); Hyun KANG, Hwaseong-si, Gyeonggi-do (KR)

(73) Assignee: TEPS CO., LTD., Hwaseong-si, Gyeonggi-do (KR)

(21) Appl. No.: 16/464,507

(22) PCT Filed: Jan. 2, 2018
(86) PCT No.: PCT/KR2018/000067

§ 371 Date: May 28, 2019

(30) Foreign Application Priority Data
Jan. 3, 2017 (KR) 10-2017-0000706

(51) Int. Cl. G01R 31/28; G01R 1/073

(52) U.S. Cl. CPC G01R 31/2863; G01R 31/2889; G01R 1/07342

(57) ABSTRACT

Disclosed is a probe card including: a plurality of probes configured to come into contact with a test body and transfer electrical signals thereto; a probe printed circuit board (PCB) on which signal wirings are formed to distribute the electrical signals and transfer the distributed electrical signals to the plurality of probes; a first guide plate disposed to face the test body and formed with a plurality of probe holes into which one ends of the plurality of probes are inserted; and a second guide plate disposed in parallel with the first guide plate and formed with a plurality of probe holes into which the other ends of the plurality of probes are inserted. The signal wirings on the probe PCB and the other ends of the plurality of probes are directly and electrically connected to each other through coaxial cables.

### CROSS-REFERENCE TO PRIOR APPLICATIONS

This application is a National Stage patent application of PCT International Patent Application No. PCT/KR2018/000067 filed on Jan. 2, 2018 under 35 U.S.C. § 371, which claims priority to Korean Patent Application No. 10-2017-0000706 filed on Jan. 3, 2017, which are all hereby incorporated by reference in their entirety.

### BACKGROUND

The present invention relates to a probe card, and more particularly, to a vertical-type probe card capable of coping with a fine pitch and effectively suppressing a leakage current.

With the development of the information technology (IT) industry in recent years, semiconductor chips are widely used in various fields such as computers, mobile phones, displays, game machines, home appliances, automobiles, and the like. These semiconductor chips are subjected to a pre-inspection to determine a pass/fail by evaluating whether the chips operate normally at each stage of a manufacturing process until the semiconductor chips are packaged in the final stage and mounted on finished products.

Out of the semiconductor inspection stages, the inspection in a wafer state is performed by inspecting an electrical operation of each chip at a wafer level before dicing hundreds to thousands of semiconductor chips made on a semiconductor wafer into individual chips and proceeding to an assembly process, and the inspection in a wafer state enables cost reduction in subsequent packaging stages by prefiltering chip defects at the wafer level. A probe card is a device used for the inspection in such a wafer state and electrically connects the wafer and main inspection equipment to transfer test signals from the main inspection equipment to pads on the wafer. Specifically, the probe card includes a plurality of probes in the form of a needle, and each of the plurality of probes comes into contact with the pad of a semiconductor device on the wafer so that the test signals from the main inspection equipment are applied to the wafer pad.

In recent years, with the high-density integration of semiconductor devices, the number of input/output (I/O) pads of the semiconductor chip is increasing, and pad spacing (pitch) is also becoming finer. As described above, as the size and arrangement structure of the semiconductor device are continuously reduced, development of the probe card having a large number of inspection needles and capable of effectively coping with a fine pitch is urgently required.

The probe cards are mainly divided into horizontal-type probe cards, probe cards using a micro electro mechanical systems (MEMS) technology, vertical-type probe cards, and the like according to the form thereof. Among these, the horizontal-type probe cards and the MEMS probe cards generally have a problem of causing significant damages to the wafer pads by generating linear scrubs on the wafer pads due to characteristics of a probe structure. Such damages generated on the wafer pads become more fatal as the size of the wafer pads becomes smaller with the development of wafer manufacturing process technology as described above, and thus, the vertical-type probe cards have been researched as an alternative structure to minimize the damages to the wafer pads. Unlike the conventional horizontal-type or MEMS probe cards, the vertical-type probe cards generate point-shaped scrubs on the wafer pads while coming into contact with the wafer pads, so that the damages made to the pads may be minimized relatively.

FIG. 1 is a cross-sectional view illustrating a structure of the conventional vertical-type probe card.

As shown in FIG. 1, the conventional vertical-type probe card includes a plurality of probes 101 configured to come into contact with pads on a wafer which is a test body and apply electrical signals to each of the pads, first and second guide plates 102 and 103 configured to support the plurality of probes, a probe printed circuit board (PCB) (main PCB) 105 on which signal wirings are formed to distribute electrical test signals from main inspection equipment and transfer the distributed electrical test signals to the plurality of probes 101, a space transformer (sub PCB) 104 disposed above the first and second guide plates 102 and 103 and configured to redistribute the electrical signals distributed from the probe PCB 105 and transfer the redistributed electrical signals to the plurality of probes 101, coaxial cables 106 configured to electrically interconnect solder pads on the probe PCB 105 to solder pads on the space transformer 104, and a fixing plate 107 configured to fix relative positions of the probe PCB 105 and the space transformer 104.

Among these, the space transformer 104 is a component configured to play a role of mutually transferring power and the electrical test signals between the probe PCB 105 and the plurality of probes 101, that is, a component configured to perform space transforming of electrical signal paths, and requires a material having excellent mechanical strength and chemical resistance, and is usually made of a ceramic material.

The conventional vertical-type probe card configured as described above has an advantage in that damages applied to wafer pads may be relatively minimized as described above. On the other hand, the conventional vertical-type probe card has a problem in that it is difficult to fabricate the space transformer corresponding to a fine pitch in the form of a PCB due to structural characteristics thereof, and especially the manufacturing characteristics of the space transformer among the above-described components. Due to limitations in manufacturing characteristics of the space transformer, in the conventional vertical-type probe card, a pitch interval of about 80 μm has been understood as a practical manufacturing limit, and it has been recognized that it is practically impossible to manufacture the vertical-type probe card (that is, manufacture of the space transformer) capable of coping with the finer pitch.

Further, in the conventional vertical-type probe card adopting the space transformer as a component as described above, electrical contact points are formed on three places in total in signal paths from the plurality of probes 101 to the probe PCB 105. That is, electrical contacts are made at a first contact point between the probe 101 and the space transformer 104, a second contact point at which the space transformer 104 and the coaxial cable 106 are connected to each other, and a third contact point at which the coaxial cable 106 and the solder pad on the probe PCB 105 are connected to each other. Meanwhile, as the number of the electrical contacts in the probe card increases, it may cause a leakage current between signal paths during the test, and thus it is required to reduce the number of electrical contact points as small as possible in order to prevent the leakage current.

Furthermore, since the conventional vertical-type probe card adopts the space transformer requiring excellent mechanical strength and chemical resistance as described above, an increase in overall manufacturing costs due to the use of the space transformer is also pointed out as a problem.

### SUMMARY

It is an objective of the present invention to provide a vertical-type probe card capable of coping with a fine pitch to solve the technical problems of the conventional vertical-type probe card as described above.

It is another objective of the present invention to prevent a current leakage during a test by reducing the number of electrical contact points in the probe card as compared with that of a conventional vertical-type probe card.

It is still another objective of the present invention to reduce the overall manufacturing costs of a vertical-type probe card.

According to an aspect of the present invention, there is provided a probe card including a plurality of probes configured to come into contact with a test body and transfer electrical signals thereto, a probe printed circuit board (PCB) on which signal wirings are formed to distribute the electrical signals and transfer the distributed electrical signals to the plurality of probes, a first guide plate disposed to face the test body and formed with a plurality of probe holes into which one ends of the plurality of probes are inserted, and a second guide plate disposed in parallel with the first guide plate and formed with a plurality of probe holes into which the other ends of the plurality of probes are inserted, wherein the signal wirings on the probe PCB and the other ends of the plurality of probes are directly and electrically connected to each other through coaxial cables.

The probe card further includes a cable guide plate disposed between the probe PCB and the second guide plate, and a plurality of holes are formed in the cable guide plate at positions corresponding to the other ends of the plurality of probes, and the other ends of the plurality of probes and the coaxial cables are electrically connected to each other in a state in which one ends of the coaxial cables are inserted into the plurality of holes of the cable guide plate.

Each coaxial cable may include a plurality of inner conductors and an outer conductor surrounding the plurality of inner conductors, and at one ends of the coaxial cables, one of the plurality of the inner conductors of each of the coaxial cables is inserted into one of the plurality of holes of the cable guide plate and is electrically connected to one of the other ends of the plurality of probes.

The probe card further includes a shielding member formed on the cable guide plate and configured to block a leakage current between the inner conductors of the plurality of the coaxial cables exposed to an outside of the plurality of holes of the cable guide plate.

The shielding member may include an epoxy resin.

According to the present invention, the probe card capable of sufficiently coping with a fine pitch, for example, a fine pitch of 80 μm or less, which has not been able to cope with in the past due to manufacturing limitations of a probe PCB can be provided by replacing a sub PCB adopted by a conventional vertical-type probe card with a cable guide plate and inserting a coaxial cable into the cable guide plate and directly connecting the coaxial cable to a probe.

Further, the number of electrical contacts in a probe card can be reduced by connecting a coaxial cable directly to a probe without using a sub PCB, and thus an effect of preventing a leakage current during a test can be obtained.

Further, by eliminating the use of a sub PCB, an effect of reducing overall manufacturing costs of a probe card can also be obtained.

### BRIEF DESCRIPTION OF THE DRAWINGS

FIG. 1 is a cross-sectional view illustrating a structure of a conventional vertical-type probe card.

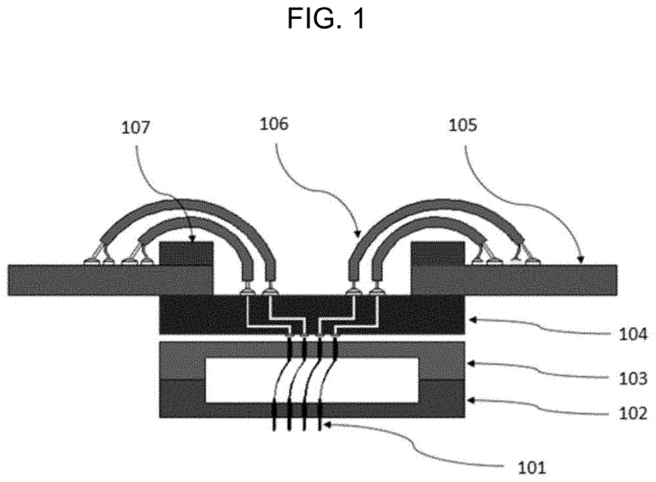

FIG. 2 is a cross-sectional view illustrating a structure of a probe card according to one embodiment of the present invention.

FIG. 3 is a cross-sectional view illustrating a cross-section of a coaxial cable.

### DETAILED DESCRIPTION

Hereinafter, embodiments of the present invention will be described in detail to aid in an understanding the present invention. However, embodiments according to the present invention may be modified into various forms and, it should not be interpreted that the scope of the present invention is limited to the embodiments. The embodiments of the present invention are provided to more fully describe the present invention to those skilled in the art.

Further, it should be noted that sizes, shapes, and the like of components shown in the accompanying drawings, which are referred to in the following detailed description, may be exaggeratedly emphasized for clarity and convenience of explanation.

Further, terms which will be described below are those defined in consideration of functions in the present invention and thus may vary according to an intention of a user or an operator, or a practice. Therefore, such terms should be defined on the basis of contents throughout the present specification.

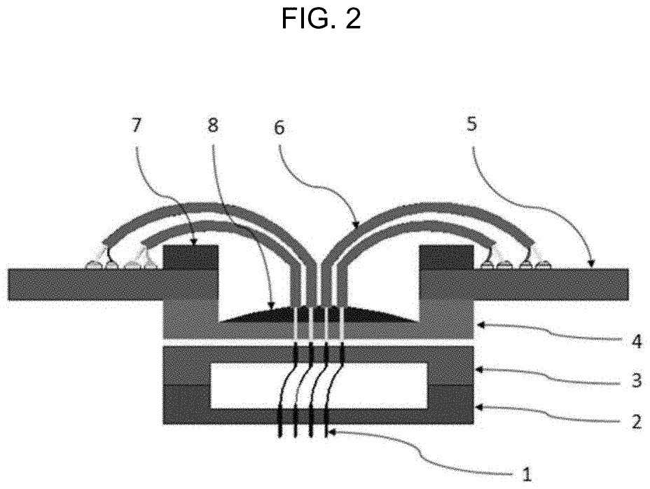

FIG. 2 illustrates a cross-sectional structure of a probe card according to one embodiment of the present invention. The probe card according to one embodiment of the present invention includes a plurality of probes 1 configured to come into contact with a test body and transfer electrical signals thereto, and a probe printed circuit board (PCB) (main PCB) 5 on which signal wirings are formed to distribute the electrical signals and transfer the distributed electrical signals to the plurality of probes 1. The plurality of probes 1 are vertically and movably supported by two guide plates (a first guide plate 2 and a second guide plate 3). The first guide plate 2 is disposed to face the test body and has a plurality of probe holes into which one ends of the plurality of probes 1 may be inserted. The second guide plate 3 is disposed above the first guide plate 2 in parallel with the first guide plate 2, and the second guide plate 3 is formed with a plurality of probe holes into which the other ends of the plurality of probes 1 may be inserted.

In the probe card according to one embodiment of the present invention, a cable guide plate 4 is disposed between the probe PCB 5 and the second guide plate 3 instead of a sub PCB performing a role of a conventional space transformer, and it is configured such that a coaxial cable is directly connected to the probe 1 through the cable guide plate 4, and such a configuration will be described in detail below.

A plurality of holes are formed in the cable guide plate 4 disposed between the probe PCB 5 and the second guide plate 3, and the plurality of holes in the cable guide plate 4 are formed at positions corresponding to the plurality of probe holes in the second guide plate 3. Solder pads on the probe PCB 5 and the plurality of probes 1 are electrically connected to each other, respectively, by coaxial cables 6 through the plurality of holes in the cable guide plate 4. Specifically, one end of each of the coaxial cables 6 makes an electrical contact with the solder pad on the probe PCB 5, and the other opposite end of each of the coaxial cables 6, which is inserted into each of the plurality of holes formed in the cable guide plate 4, is electrically connected to each of the probes exposed through the probe holes of the second guide plate 3 positioned below the cable guide plate.

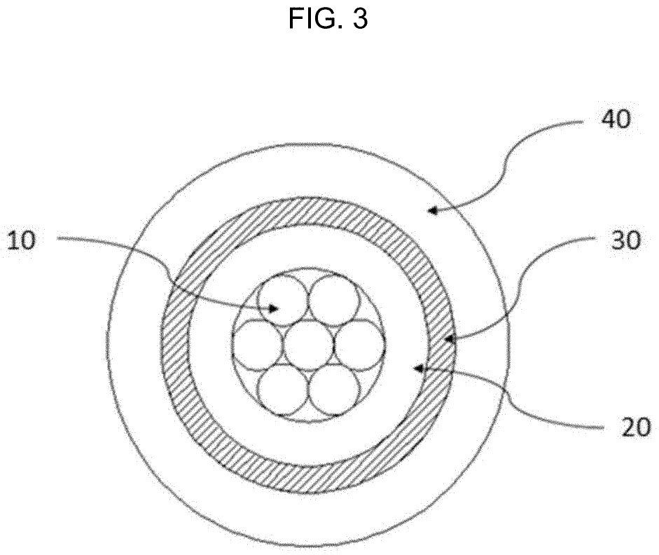

FIG. 3 is a cross-sectional view illustrating a cross-sectional structure of the coaxial cable 6. As shown in the figure, the coaxial cable 6 has a structure in which inner stranded conductors 10 positioned at the center of the coaxial cable 6 and having multiple strands and an outer conductor 30 surrounding the inner stranded conductors 10 are radially disposed with an insulator 20 interposed therebetween, and the outer conductor 30 is covered and insulated by an outer cover 40.

In one end of the coaxial cable 6, that is, in one end of a side electrically connected to the probe 1, one of the inner stranded conductors 10 disposed at the center of a cross section of the coaxial cable with outer cover stripped off is inserted into the corresponding hole in the cable guide plate 4 and electrically connected to the probe 1 exposed upward through the probe hole of the second guide plate 3.

The cable guide plate 4 is made of an electrically insulating material. The inner stranded conductors 10 of each of the coaxial cables are separated one by one, and one of the inner stranded conductors 10 is inserted into the corresponding one of the plurality of holes formed spaced apart from each other in the cable guide plate 4 made of the electrically insulating material and is electrically connected to the corresponding probe 1, so that a leakage current between adjacent cables each connected to each probe 1 may be effectively suppressed.

Meanwhile, in consideration of a case in which a part of the inner stranded conductor 10 of the coaxial cable 6 may be exposed to an outside of an upper portion (on a side opposite to the side facing the probe) of the cable guide plate 4, a leakage current blocking resin 8 capable of blocking a leakage current between the exposed adjacent inner stranded conductors 10 may be further coated on the upper portion of the cable guide plate 4. As a material of the leakage current blocking resin 8, a material such as an epoxy resin and an insulating synthetic resin may be used, but the present invention is not limited thereto. The leakage current blocking resin 8 may not only perform a function of preventing the leakage current but also play a role of fixing each exposed inner stranded conductor 10.

As described above, according to one embodiment of the present invention, the probe card sufficiently capable of coping with a fine pitch may be provided by disposing the cable guide plate, in which the plurality of holes are formed, between the probe PCB (main PCB) and the probes in place of the conventional space transformer (sub PCB), which is limited in coping with the fine pitch due to manufacturing characteristics, and by inserting one end of the coaxial cable into the hole in the cable guide plate so that a signal wiring on the probe PCB and the probe are directly and electrically connected to each other through the coaxial cable.

Further, according to the probe card of the present invention described above, the number of electrical contact points from the probe PCB to the probe may be reduced in the probe card compared with that of the conventional probe card. That is, as described above, in the conventional probe card structure using the space transformer, three electrical contact points should be made from the probe PCB to the probe, but the probe card according to the present invention has a structure in which the probe PCB and the probe are directly connected to each other through the coaxial cable without the space transformer, so that the only two electrical contact points, a first contact point between the probe 1 and the coaxial cable 6 and a second contact point between the coaxial cable 6 and the solder pad of the probe PCB 5 are made in the probe card. Through such a reduction in the number of electrical contact points, the probe card according to the present invention may more effectively suppress the leakage current during the test than before.

Further, eliminating the use of the space transformer may lead to a reduction in overall manufacturing costs of the probe card.

Although specific terms have been used to describe the present invention, the specific terms are used in a generic and descriptive sense only and not for purposes of limitation and should be understood accordingly. Accordingly, it will be understood by those of ordinary skill in the art that various changes in form and details may be made without departing from the spirit and scope of the present invention as set forth in the following claims. The scope of the following claims is to be accorded the broadest interpretation so as to encompass all such modifications and equivalent structures and functions.

1. (canceled)

2. (canceled)

3. A probe card comprising:
a plurality of probes configured to come into contact with a test body and transfer electrical signals thereto;
a probe printed circuit board (PCB) on which signal wirings are formed to distribute the electrical signals and transfer the distributed electrical signals to the plurality of probes;
a first guide plate disposed to face the test body and formed with a plurality of probe holes into which one ends of the plurality of probes are inserted;
a second guide plate disposed in parallel with the first guide plate and formed with a plurality of probe holes into which the other ends of the plurality of probes are inserted, and
a cable guide plate disposed between the probe PCB and the second guide plate,
wherein the signal wirings on the probe PCB and the other ends of the plurality of probes are directly and electrically connected to each other through coaxial cables,
wherein a plurality of holes are formed in the cable guide plate at positions corresponding to the other ends of the plurality of probes, and the other ends of the plurality of probes and the coaxial cables are electrically connected to each other in a state in which one ends of the coaxial cables are inserted into the plurality of holes of the cable guide plate, and
wherein each of the coaxial cables includes a plurality of inner conductors and an outer conductor surrounding the plurality of inner conductors, and at one ends of the coaxial cables, one of the plurality of inner conductors of each of the coaxial cables is inserted into one of the plurality of holes of the cable guide plate and is electrically connected to one of the other ends of the plurality of probes.

4. The probe card of claim 3, further comprising a shielding member formed on the cable guide plate and configured to block a leakage current between the inner conductors of the plurality of the coaxial cables exposed to an outside of the plurality of holes of the cable guide plate.

5. The probe card of claim 4, wherein the shielding member includes an epoxy resin.
